(19) United States
(12) Patent Application Publication
(10) Pub. No.: US 2007/0247811 A1
(43) Pub. Date: Oct. 25, 2007

(54) Electronic device

(76) Inventor: Hideaki Ohmi, Kariya-shi (JP)

Correspondence Address: MORGAN & FINNEGAN, L.L.P., 3 World Financial Center, New York, NY, 10281-2101, US

(21) Appl. No.: 11/787,800

(22) Filed: Apr. 18, 2007

(30) Foreign Application Priority Data
Apr. 19, 2006 (JP) P2006-115940

(51) Int. Cl. H05K 7/20

(52) U.S. Cl. 361/697

(57) ABSTRACT

An electronic device comprises a casing, a heat sink accommodated in the casing and formed in a shape so as to have an air passage, a fan accommodated in the casing adjacent to one end of the heat sink, and a circuit board on which a heating element and a coil part are mounted. The circuit board is accommodated in the casing. The heating element is provided so that heat of the heating element is transmittable to the heat sink, and the coil part is disposed in an air course on an opposite side of the heat sink with respect to the fan.

### BACKGROUND OF THE INVENTION

The present invention relates to an electronic device, more particularly to an electronic device, such as a power supply or the like, in which a heating part and a heat sink, for radiating heat of the heating part, is provided on a printed circuit board and accommodated in the casing.

In an electronic device having heating parts in its casing, heat sinks are utilized with the respective heating parts to prevent the heating parts from overheating. The heat from the heating parts is radiated away from the heating parts and into the inside of the casing via the heat sinks, and the resulting heated air in the casing is exhausted out of the casing via a fan. However, when the amount of heat generated by the heating parts increases proportionately with an increase of electric power, the area of the heat sinks for heat radiation becomes insufficient. In the case where the heat sinks are provided for respective heating parts, and the air in the casing is exhausted out of the casing by the fan, the air flows sufficiently through some part of the inside of the casing and insufficiently through some other part thereof. As a whole, the air fails to flow sufficiently around all locations which correspond to the heat sinks for the heating parts.

Japanese Patent No. 2594274 discloses an uninterruptible power supply having a cabinet which accommodates therein a main circuit unit, an output transformer, a battery, an input output element, and a fan. The main circuit unit includes a printed circuit board on which semiconductors, electronic parts and radiating blocks are mounted and a cooling fin which is connected to the printed circuit board through the radiating blocks. In the uninterruptible power supply, an output transformer 61 as a heating source and a main circuit unit 62 are aligned in planar arrangement between an inlet 64 which is formed in the cabinet 63 and a cooling fan 65 as shown in FIG. 5. A rectangular-shaped air duct is formed by a printed circuit board 66 and a casing 67 of the main circuit unit 62. The semiconductors, and the radiating blocks and the cooling fin of the main circuit unit 62 are disposed in the air duct.

Japanese Patent Application No. 2005-142379 discloses an electronic device having a casing and a printed circuit board which is installed in the casing. A heat radiating member, electronic parts and a fan are mounted on the surface of the printed circuit board. The heat radiating member (or a heat sink) serves to cool the electronic parts efficiently and support the printed circuit board and the casing when external force is applied to the electronic device. In the electronic device, a heat radiating member 72, a fan 73, and electronic parts 74 are mounted on the surface of a printed circuit board 71 as shown in FIG. 6. The heat radiating member 72 is mounted substantially perpendicularly to the printed circuit board 71 and has a substantially U-shaped cross section. The heat radiating member 72 is located in the center of the printed circuit board 71 in the width direction, and the electronic parts 74 which generate a large amount of heat are disposed on the printed circuit board 71 in contact with the heat radiating member 72. The fan 73 is disposed adjacent to one end of the heat radiating member 72 so as to exhaust air from the inside of the heat radiating member 72 out of the casing (not shown).

When the number of parts to be cooled is large, in the radiating structure in which the parts to be cooled are aligned between the inlet 64 and the cooling fan 65 as disclosed in the Japanese Patent No. 2594274, cooling efficiency deteriorates for the parts other than the parts which are located so as to face the inlet 64 and the cooling fan 65.

In the radiating structure as disclosed in the Japanese Patent Application Publication 2005-142379, the electronic parts 74 which are disposed in contact with the heat radiating member 72 are efficiently cooled. However, cooling efficiency is low for the parts which are mounted on the printed circuit board 71 and out of contact with the heat radiating member 72. Thus, it is hard to radiate heat efficiently and downsize the heat sink in the power supply which uses many heating parts such as a heating element, a transformer, a coil and the like.

The present invention, which is made in view of the above problems, is directed to an electronic device which enhances the efficiency of dissipating heat away from the heating parts such as a heating element, a transformer, a coil or the like and downsizes a heat sink.

### SUMMARY OF THE INVENTION

An aspect according to the present invention provides an electronic device which comprises a casing, a heat sink accommodated in the casing and formed in a shape so as to have an air passage, a fan accommodated in the casing adjacent to one end of the heat sink, and a circuit board on which a heating element and a coil part are mounted. The circuit board is accommodated in the casing. The heating element is provided so that heat of the heating element is transmittable to the heat sink, and the coil part is disposed in an air course on an opposite side of the heat sink with respect to the fan.

Other aspects and advantages of the invention will become apparent from the following description, taken in conjunction with the accompanying drawings, illustrating by way of example the principles of the invention.

### BRIEF DESCRIPTION OF THE DRAWINGS

The features of the present invention that are believed to be novel are set forth with particularity in the appended claims. The invention together with objects and advantages thereof, may best be understood by reference to the following description of the presently preferred embodiments together with the accompanying drawings in which:

FIG. 1 is a perspective interior view of an electronic device of a preferred embodiment according to the present invention when a cover is removed therefrom;

FIG. 2 is a perspective view of a heat sink of the preferred embodiment according to the present invention;

FIG. 3 is a plan view of the electronic device of the preferred embodiment;

FIG. 4 is a front view of the electronic device of the preferred embodiment showing the heat sink and electronic parts below the heat sink,

FIG. 5 is a plan view of an uninterruptible power supply according to prior art; and

FIG. 6 is a perspective view of the interior of an electronic device according to prior art.

### DETAILED DESCRIPTION OF THE PREFERRED EMBODIMENTS

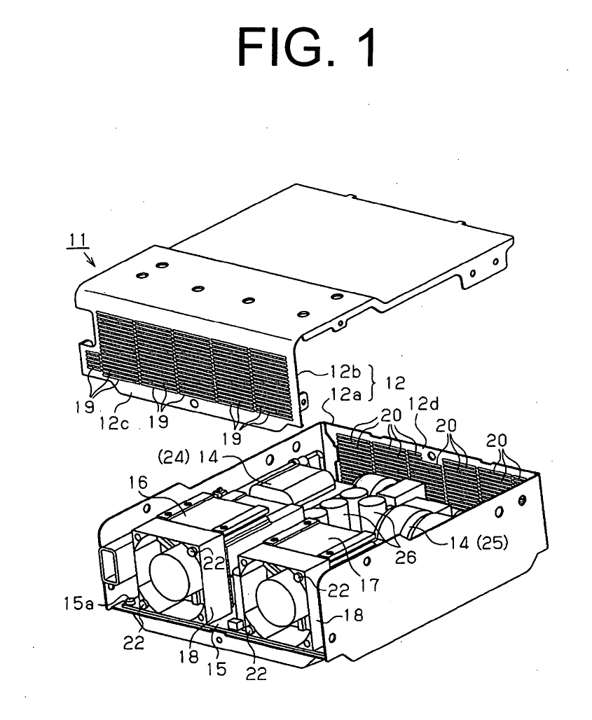

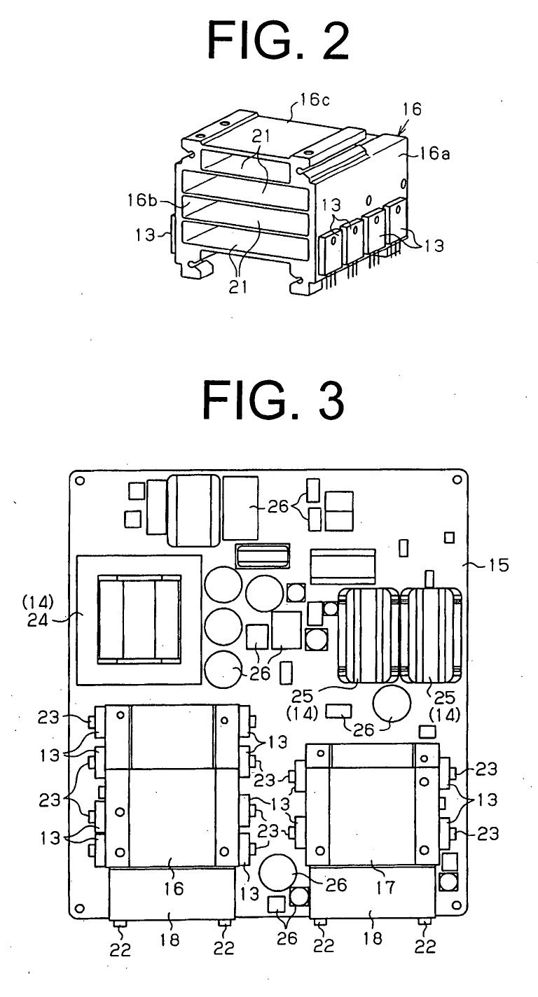

The following will describe a power supply of a preferred embodiment according to the present invention with reference to FIGS. 1 through 4. Referring to FIG. 1, a power supply 11 as an electronic device includes a casing 12, a circuit board 15 on which heating elements 13 (shown in FIGS. 2 and 3) and coil parts 14 are mounted, a plurality of heat sinks 16 and 17 (two in this preferred embodiment), and a plurality of fans 18 (two in this preferred embodiment). The circuit board 15, the heat sinks 16 and 17 and the fans 18 are accommodated in the casing 12. A printed board is used as the circuit board 15.

The casing 12 includes a main body 12a and a cover 12b, each provided by forming iron sheet into a predetermined shape. The main body 12a and the cover 12b are fixed to each other by screws (not shown). The cover 12b is also fixed to the heat sinks 16 and 17 by screws (not shown). The main body 12a is formed in the shape of a square box one of the side walls of which is removed therefrom. The cover 12b is formed in a substantially L-shape so that the cover 12b covers the main body 12a. The cover 12b has a first side wall 12c which is disposed perpendicularly to the bottom wall of the main body 12a when the cover 12b is fixed to the main body 12a. The first side wall 12c has air vents 19 which are formed in the entire surface thereof by slits. The main body 12a has a second side wall 12d which faces the air vents 19. The second side wall 12d has air vents 20 which are formed in the entire surface thereof by slits. Each of the slits is formed with such a width so as to prevent a wire with 1 mm diameter from passing therethrough. The circuit board 15 is fixed to the bottom wall of the main body 12a by screws 15a (one being shown in FIG. 1).

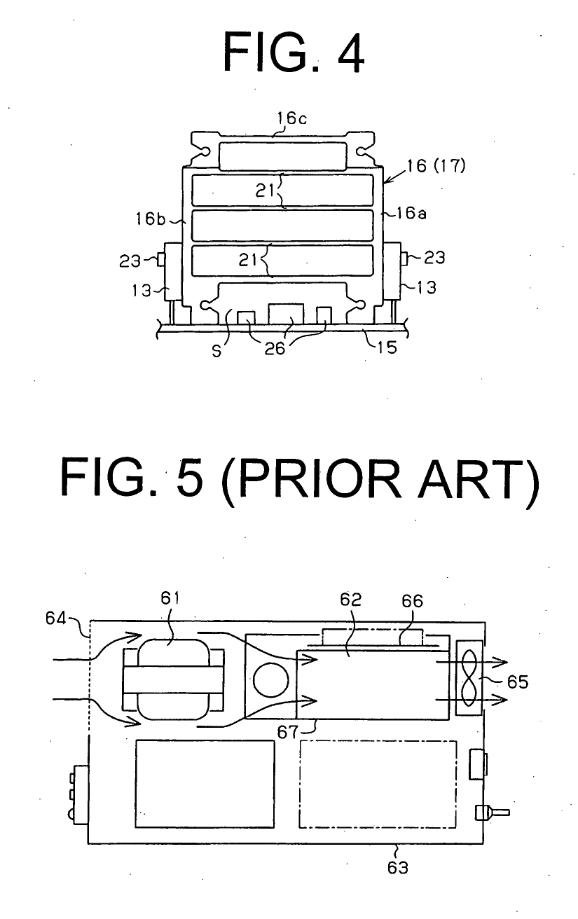

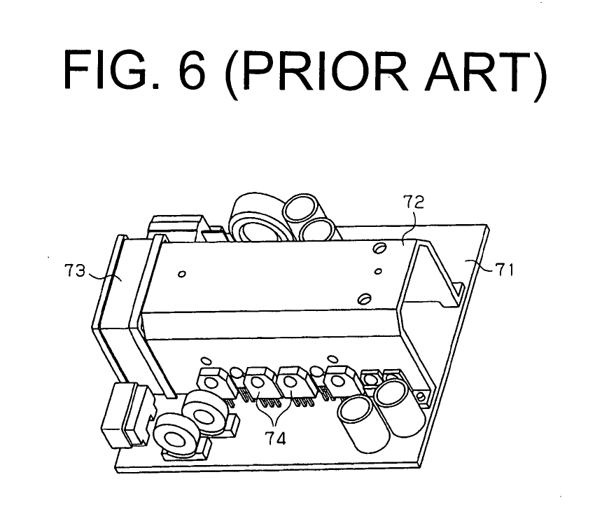

Referring to FIGS. 2 and 4, the heat sink 16 is formed in a shape so as to have an air passage. More specifically, the heat sink 16 has a substantially U-shaped cross section having side walls 16a and 16b and an upper wall 16c which connects the upper ends of the side walls 16a and 16b. The heat sink 16 has a plurality of fins 21 which are provided between the side walls 16a and 16b in parallel with the upper wall 16c. As shown in FIG. 4, among the fins 21, the fin 21 which is closest to the circuit board 15 is disposed so as to provide a space S between the fin 21 and the circuit board 15 for accommodating electronic parts therein. Namely, the fins 21 are connected perpendicularly to the inner surfaces of the side walls 16a and 16b and disposed so as to extend along the flow of air which is blown from the fan 18 and so as to provide the space S for accommodating electronic parts therein. The heat sink 17 has basically the same structure as the heat sink 16 but is shorter in length than the heat sink 16.

Referring to FIGS. 1 and 3, the heat sinks 16 and 17 are disposed so that the air passages thereof are parallel with each other. The fans 18 are disposed on ends of the heat sinks 16 and 17, respectively. The fans 18 are provided so as to draw air from the outside of the casing 12 through the air vents 19 and blows the air into the air passages of the heat sink 16 and 17. The fans 18 are fixed to the heat sinks 16 and 17 by bolts 22.

Referring to FIGS. 3 and 4, the heating elements 13 which generate large amounts of heat among the electronic parts on the circuit board 15 are fixed to the outer surfaces of the side walls of the heat sinks 16 and 17 by screws 23. In other words, the heating elements 13 are provided so that the heat thereof is transmittable to the heat sinks 16 and 17. The heating elements 13 include switching devices, diodes and the like.

The heat sinks 16 and 17 are disposed on the circuit board 15 so as to provide predetermined spaces between the heating elements 13 and the main body 12a and between the heating elements 13 which are fixed to the heat sink 16 and the heating elements 13 which are fixed to the heat sink 17. Thus, the fans 18 do not face the whole area of the air vents 19 of the casing 12, that is, the air vents 19 are also formed in the part (a second part) of the first side wall 12c other than the part (a first part) thereof which faces the fans 18.

A transformer 24 and coils 25 as the coil part 14 are located in an air course on the opposite side of the heat sinks 16 and 17 with respect to the fans 18. The air course is a path in which the air flows toward and out of the air passages of the heat sinks 16 and 17. Electronic parts 26 other than the heating elements 13, the transformer 24 and the coils 25 are mounted on the circuit board 15 between the transformer 24 or the coils 25 and the air vents 20, between the transformer 24 and the coils 25, between the heat sink 17 and the coils 25, and between the heat sinks 16 and 17. The electronic parts 26 include capacitors, resistors, central processing units (CPU), memories and the like.

Referring to FIG. 4, electronic parts 26 are mounted on the circuit board 15 below the lowest fins 21 of the heat sink 16 and 17 (in the space S). Though the bottom wall of the casing 12 corresponds to the lower side of the power supply 11 in the preferred embodiment, the power supply 11 may not be used so that the bottom wall of the casing 12 corresponds to the lower side thereof. For example, the power supply 11 is fixed in a place so that the bottom wall of the casing 12 extends vertically or is inclined.

The following will describe the operation of the power supply 11 constructed thus. The power supply 11 is in an operational state when connected to a power source. When the power supply 11 is driven, the fans 18 are also driven. As the fans 18 are driven, the air is drawn from the outside of the casing 12 into the casing 12 through the part of the air vents 19 in the first part of the first side wall 12c and blown toward the air passages of the heat sinks 16 and 17. The air which is blown toward the air passages of the heat sink 16 and 17 flows therethrough toward the transformer 24 and the coils 25. After contacting with the transformer 24 and the coils 25, a part of the air flows through a space between the transformer 24 or the coils 25 and the cover 12b, a space above the electronic parts 26 and the air vents 20 to the outside of the casing 12. A part of the air flows through a space between the transformer 24 and the coil 25 while contacting with the electronic parts 26, and then flows out of the casing 12.

A part of the air contacts with the transformer 24, the coils 25 and the electronic parts 26 to change its direction toward a space between the heat sinks 16 and 17, a space between the heat sink 16 and the side wall of the casing 12, or a space between the heat sink 17 and the side wall of the casing 12. This air flows out of the casing 12 through the air vents 19.

### The preferred embodiment offers the following advantageous effects.

(1) The casing 12 of the power supply 11 accommodates therein the circuit board 15 on which the heating elements 13, the coil parts 14 (or the transformer 24 and the coils 25) and the like are mounted, a plurality of the heat sinks 16 and 17 and the fans 18. Each of the heat sinks 16 and 17 are formed in a shape so as to have air passages. The heat sinks 16 and 17 are disposed so that the air passages thereof are parallel with each other. The fans 18 are disposed on the ends of the heat sinks 16 and 17, respectively. The heating elements 13 are provided so as to contact the heat sink 16 or 17, and the coil parts 14 are located in the air course on the opposite side of the heat sinks 16 and 17 with respect to the fans 18. Thus, air flows through the air passages of the heat sink 16 and 17 when the fans 18 are driven, and the heating elements 13 in contact with the heat sinks 16 and 17 are efficiently cooled. In addition, the coil parts 14 which are located in the air course are efficiently cooled. As a result, efficiency of cooling the heating parts is enhanced and the heat sinks 16 and 17 are downsized.

(2) The fans 18 are provided so as to draw the air from the outside of the casing 12 and so as to blow the air toward the air passages of the heat sinks 16 and 17, respectively. Thus, the air which is drawn from the outside of the casing 12 is blown toward the coil parts 14, namely, the transformer 24 and the coils 25 so that the air efficiently contacts with the coil parts 14, thereby enhancing efficiency of cooling the coil parts 14. When the fins 21 are provided in the air passage of the heat sinks 16 and 17 and the fans 18 are provided so as to draw the air in the casing 12 from the air passages of the heat sinks 16 and 17 and so as to exhaust the air out of the casing 12 through the air vents 19 which faces the fans 18, a whir of the fans 18 tends to occur. When the fans 18 are provided so as to draw the air from the outside of the casing 12 and so as to blow the air toward the air passages of the heat sinks 16 and 17, however, the whir of the fans 18 is suppressed.

(3) The air vents 19 are formed in the part of the first side wall 12c of the casing 12 other than the part thereof which faces the fans 18, and the air blown from the fans 18 can be exhausted out of the casing 12 through the air vents 19. Thus, the wind (air) which contacts with the coil parts 14 changes its direction to flow through the outside of the heat sinks 16 and 17 and is exhausted out of the casing 12 through a part of the air vents 19 other than the part thereof which face the fans 18. The wind contributes to cooling the heating elements 13 and the electronic parts 26 which are located outside and adjacent to the heat sink 16 or 17.

(4) The fins 21 are formed on the side walls 16a and 16b. Thus, efficiency of cooling the heating elements 13 is greater than that when the fins 21 are formed on the upper wall 16c.

(5) Each of the heat sinks 16 and 17 has the substantially U-shaped cross section. The fins 21 are provided so as to be perpendicular to the inner surfaces of the side walls of the heat sinks 16 and 17, so as to extend along the flow of the air which is blown from the fans 18, and so as to provide the space S for accommodating therein the electronic parts 26. The electronic parts 26 are mounted on the circuit board 15 in the space S. Thus, while the efficiency of cooling the heat sinks 16 and 17 is enhanced, the electronic parts 26 are mounted more efficiently by using the space S. As a result, the casing 12 or the power supply 11 is made smaller in size.

(6) The casing is constructed of an iron sheet. This facilitates a process of bending and a process of forming slits of the air vents 19 and 20 in forming the casing 12, in comparison to where the casing 12 is constructed of an aluminum sheet. In addition, this reduces cost of material in comparison with the case of using an aluminum sheet. The heat conductivity of an iron sheet is lower than that of an aluminum sheet. However, the heat which is generated by the heating elements 13 and the coil parts 14 is radiated to the outside of the casing 12 by the effects of the heat sinks 16 and 17. Thus, even though the cover 12b is constructed of an iron sheet, the heating elements 13 and the coil parts 14 are efficiently cooled.

(7) The casing 12 (or the cover 12b) is fixed to the heat sinks 16 and 17 by the screws. Thus, heat is radiated from the heat sinks 16 and 17 to the casing 12.

The present invention is not limited to the preferred embodiments described above, but it may be practiced in various alternative embodiments, as exemplified below.

The fans 18 are provided so as to draw the air from the outside of the casing 12 and so as to blow this air toward the air passages of the heat sinks 16 and 17 in the preferred embodiment. However, the fans 18 may be provided so as to draw the air from the air passages of the heat sinks 16 and 17 and to exhaust this air out of the casing 12 through the air vents 19. The air vent 19 may be formed only in the first part of the first side wall 12c of the casing 12 which faces the fans 18.

As long as the heating elements 13 are provided so that the heat thereof is transmissible to the heat sink 16 or 17, the heating elements 13 do not have to be in direct contact with the heat sink 16 or 17. Alternatively, a heat transfer member such as a radiating sheet or the like may be disposed between the heating elements 13 and the heat sink 16 or 17. In this case, the heat which is generated by the heating elements 13 is transmitted to the heat sink 16 or 17 through the heat transfer member more efficiently than the case where the heating elements 13 are directly fixed to the heat sink 16 or 17 by the screw 23.

The fins 21 which are provided in the heat sinks 16 and 17 connect the side walls 16a and 16b of the heat sinks 16 and 17 in the preferred embodiment. Alternatively, the fins 21 may extend from either of the side walls.

The fins 21 which are provided in the heat sinks 16 and 17 are in parallel with the upper walls 16c of the heat sinks 16 and 17. Alternatively, the fins 21 may extend downwardly from the upper walls 16c of the heat sinks 16 and 17. However, the provision of the fins 21 on the side walls 16a and 16b enhances the effect of cooling the heating elements 13 in comparison to the above alternative embodiment.

The fins 21 may be removed from the heat sinks 16 and 17. The casing 12 is not limited to be formed of an iron sheet but may be formed of an aluminum sheet.

The shapes of the main body 12a and the cover 12b of the casing 12 are not limited to the shapes of the preferred embodiment. For example, the main body 12a may have a box shape whose top is opened and the cover 12b may be a flat plate for covering the opening of the main body 12a.

The fans 18 may be spaced at an interval from the heat sinks 16 and 17, respectively. The number of the heat sinks 16 and 17 are not limited to two but may be three or more. Alternatively, only one heat sink may be provided in the electric device.

The cross sections of the heat sinks 16 and 17 are not limited to the substantially U-shaped cross section but may be shaped so that the upper wall is bent or curved.

Therefore, the present examples and embodiments are to be considered as illustrative and not restrictive, and the invention is not to be limited to the details given herein but may be modified within the scope of the appended claims.

What is claimed is:

1. An electronic device comprising:
a casing;
a heat sink accommodated in the casing, the heat sink being formed in a shape so as to have an air passage;
a fan accommodated in the casing, the fan being adjacent to one end of the heat sink; and
a circuit board on which a heating element and a coil part are mounted, the circuit board being accommodated in the casing, the heating element being provided so that heat of the heating element is transmittable to the heat sink, the coil part being disposed in an air course on an opposite side of the heat sink with respect to the fan.

2. The electronic device according to claim 1, wherein the fan is provided so as to draw air from outside of the casing and so as to blow the air into the air passage of the heat sink.

3. The electronic device according to claim 2, wherein the casing has a first side wall adjacent to the fan, the first side wall having an air vent which is formed in a first part of the first side wall which faces the fan.

4. The electronic device according to claim 3, wherein the air vent is further formed in a second part of the first side wall other than the first part of the first side wall, the air which is blown from the fan and contacts with the coil part to change a direction thereof is exhausted out of the casing through a part of the air vent in the second part.

5. The electronic device according to claim 3, wherein the casing has a second side wall which faces the first side wall, the second side wall having an air vent.

6. The electronic device according to claim 1, wherein the heat sink has a shape having two side walls and an upper wall which connects upper ends of the side walls, the heat sink having a fin which is substantially perpendicular to one of the side walls and the upper wall of the heat sink and extends along a flow direction of the air which is blown from the fan, a space being provided between the fin and the circuit board for accommodating therein an electronic part.

7. The electronic device according to claim 6, wherein the fin is formed on the side wall of the heat sink, the fin being substantially parallel with the upper wall.

8. The electronic device according to claim 1, wherein the casing is formed of an iron sheet.

9. The electronic device according to claim 1, wherein a plurality of the heat sinks and a plurality of the fans are accommodated in the casing, the air passages of the heat sinks being substantially parallel with each other, the fans being respectively disposed on one ends of the heat sinks.

10. The electronic device according to claim 1, wherein the heating element is provided so as to contact the heat sink directly or indirectly.

11. The electronic device according to claim 1, wherein the heat sink is disposed on the circuit board.

12. The electronic device according to claim 1, wherein the casing comprises a cover which is fixed to the heat sink.
